(19) United States
(12) Patent Application Publication
(10) Pub. No.: US 2003/0070608 A1
(43) Pub. Date: Apr. 17, 2003

(54) Method for producing components and ultrahigh vacuum CVD reactor

(76) Inventors: Hans Martin Buschbeck, Sevelen (CH); Philipp Bartholet, Azmoos (CH); Siegfried Wiltsche, Feldkirch (AT); Jurgen Ramm, Sevelen (CH)

Correspondence Address: NOTARO & MICHALOS P.C., Suite 110, 100 Dutch Hill Road, Orangeburg, NY, 10962-2100, US

(21) Appl. No.: 09/975,885

(22) Filed: Oct. 12, 2001

(51) Int. Cl. C30B 23/00; C30B 25/00; C30B 28/12; C30B 28/14

(52) U.S. Cl. 117/86

(57) ABSTRACT

A method, installation and reactor is for the production of components or of their intermediate products. Each component in the process of being produced as a structural member, is subjected to a treatment process and several of the structural members are simultaneously subjected to a common CVD process under conditions of ultrahigh vacuum. The treatment process is a vacuum process and from it the structural members are supplied to the CVD process under vacuum.

The present invention relates to the field of production of semiconductor components or intermediate products therefor or, more generally, of components of whose production the same high requirements are made as in semiconductor component production, in particular as far as the process purity is concerned.

By “component” is here and subsequently understood a ready-to-use structure, commercially tradable as such, for example, such components can be semiconductor chips.

In the production “structural members” are treated, which lastly lead to said “components”. A “structural member”, for example a semiconductor wafer, after its treatment lastly leads to providing one or more components: for example, from one treated wafer as a structural member, one or more chips are provided as components.

The addressed components are in particular also optoelectric, optic or micromechanical components or their intermediate products.

For the deposition of thin layers within the scope of said production methods are competing PVD methods (Physical Vapor Deposition) and CVD methods (Chemical Vapor Deposition).

The present invention builds on problems which have resulted in the layer deposition of the above type by means of CVD methods.

The known CVD layer deposition methods can be differentiated according to the partial pressure of the residual gas (UHV) and the process pressure (AP-CVD, LP-CVD), which is established before or while a gas to be reacted—the process gas—is supplied to the process. Therein can be differentiated:

AP-CVD (Atmospheric Pressure CVD), in which the process gas pressure Pₚ corresponds substantially to atmospheric pressure.

LP-CVD (Low Pressure CVD), in which the process gas pressure Pₚ is set to the range of 0.1 mbar to 100 mbar.

UHV-CVD (Ultra High Vacuum CVD), in which the partial pressure of the residual gas is maximally 10⁻⁸ mbar and the process gas pressure is typically in the range of 10⁻¹ to 10⁻⁵.

For the production of components/intermediate products with a quality satisfactory in semiconductor fabrication, UHV-CVD and LP-CVD methods compete in specific areas, especially in the SiGe technology.

For example, U.S. Pat. No. 5,181,964 discloses a UHV-CVD method, in which disk-form structural members are introduced in batches, each positioned vertically and oriented one matched to another horizontally within the batch, a horizontal “stack”, into a UHV-CVD reactor and coated there. With respect to the UHV-CVD reactors further reference can be made to U.S. Pat. No. 5,607,511, with respect to known UHV-CVD processes to U.S. Pat. No. 5,298,452 as well as U.S. Pat. No. 5,906,680. Furthermore, reference is made to B. S. Meyerson, IBM J. Res. Develop., Vol. 34, No. Nov. 6, 1990.

Furthermore, with respect to batch treatment of structural members, reference can be made to the following documents by the applicant:

U.S. Pat. No. 6,177,129

U.S. Pat. No. 5,515,986

U.S. Pat. No. 5,693,238.

At this place it will be noted, that if, within the scope of the present application, CVD processes are mentioned, processes will be addressed, which are not plasma-enhanced, unless specific reference is made to plasma enhancement.

While within the scope of UHV-CVD methods, for example by means of the reactors described in U.S. Pat. No. 5,181,964, batch methods are known, i.e. methods in which several structural members are simultaneously subjected to the CVD process, in LP-CVD methods customarily in each instance only one single structural member is subjected simultaneously to the CVD method. Since, due to the necessary low process temperatures (careful structural member treatment), both methods allow only relatively low coating rates, a system, which in this instance only CVD-treats individual structural members simultaneously, is disadvantageous with respect to throughput compared to a UHV-CVD method, which makes possible the batch CVD treatment. But, on the other hand, handling of individual structural members in the LP-CVD method, makes possible the automatic handling under vacuum to and from the CVD treatment process or LP-CVD reactor and from and to preceding or succeeding further treatment processes or stations.

In the UHV-CVD processes the structural member batch in production is transported in clean-room ambient atmosphere to the UHV-CVD reactor and away from it, from a or to a preceding or succeeding treatment process.

With respect to industrial fabrication, where the throughput, of course while maintaining quality requirements, is a critical parameter, both described competing methods are consequently not optimal.

The present invention is based on the task of proposing methods for the production of components or of their intermediate products, which eliminate said disadvantage to a decisive degree while ensuring said quality requirements that must be met in the production of semiconductor components, in particular in terms of process purity.

According to the invention this is attained under a first aspect with a method for the production of components or of their intermediate products, in which the component in production as a structural member

(a) is subjected to a treatment process and in a next step,

(b) several structural members can simultaneously be subjected to a CVD process under conditions of ultrahigh vacuum, and

in which said treatment process is also a vacuum process and the structural members are supplied from it under vacuum to the CVD process.

In the solution of the posed task, consequently, the present invention builds on one of said competing methods, namely on the UHV-CVD method, in which structural members are subjected in batches to the CVD process under conditions of UHV. But, here, a treatment process preceding the CVD process for the structural members is also realized as a vacuum process, and from it the structural members are furthermore supplied under vacuum to the CVD process.

Therewith the advantages of the UHV-CVD processes are retained—with batch treatment—and the advantages only known from LP-CVD, and there readily realizable due to the treatment of individual structural members, are assumed, namely developing a treatment process preceding the addressed coating process as a vacuum process, and additionally, carrying out the transport from said preceding treatment process to the layer deposition process also under vacuum. Thus, in particular the preceding critical phase in known UHV-CVD methods of the structural member transport in clean-room ambient atmosphere is now omitted, whose degree of purity, even when maintaining the most stringent specifications, can scarcely be mastered.

But, under a second aspect of the present invention, the above stated task is also solved with a method for the production of structural members or their intermediate products, in which several of the structural members are simultaneously subjected to a common CVD process under conditions of ultrahigh vacuum, wherein now the structural members are disk-form, thereby that these are subjected horizontally oriented to the CVD process under conditions of ultrahigh vacuum.

Under this second aspect as a basis is thus assumed that of the two competing methods of the above type, the UHV-CVD method presents itself to solve said task. It is further recognized here that in principle in the known UHV-CVD methods with structural members in batch treatment the customary vertical orientation of the disk-form structural members in the batch (see U.S. Pat. No. 5,181,964) with respect to the preceding and/or succeeding handling of the structural members is of disadvantage and, within the framework of the posed task, is extremely restrictive for an automated component production.

Therewith, the above described task is also already solved thereby that in the UHV-CVD batch treatment of structural members, provided these are disk-form, they are subjected with horizontal orientation to said CVD process under conditions of ultrahigh vacuum.

According to the first aspect of the present invention, in a preferred embodiment of the method according to the invention, it is combined with the procedure according to the second aspect. Consequently, a method is preferably proposed in which, on the one hand, the preceding treatment process is a vacuum process and from it the structural members are supplied under vacuum to the CVD process under UHV conditions, but in which, additionally, the structural members, now disk-form, are in their horizontal orientation, subjected to said treatment as well as also to the CVD process, and are also transported in this horizontal orientation from the treatment process into the CVD process.

In the production of components of said type, it is customary, even necessary, to set up immediately before the CVD layer deposition process a cleaning process of the structural members. In the known UHV-CVD methods, the surface to be subsequently CVD-coated is cleaned of contamination and of naturally formed oxides thereby that a cleaning method, comprising optionally several treatment steps, which customarily is terminated with a treatment of the structural members in dilute hydrofluoric acid, the so-called HF dipping. After this concluding step of the cleaning method, the structural members are transferred into the CVD process volume within the minimum feasible time, such that during the transport through the clean-room atmosphere no repeat contaminations of the structural member surface to be coated occurs. In a preferred embodiment of the method according to the invention the structural members now remain under vacuum between a cleaning process preceding the CVD process and the CVD process.

But since according to the present invention under the last stated aspect the transport of the structural members lastly toward the CVD process takes place under vacuum, it is no longer absolutely necessary that the treatment process itself, taking place immediately before the CVD process, is the cleaning process, unless the vacuum is left, it is possible to interconnect between the cleaning process and the UHV-CVD process, for example an intermediate storing process or a tempering process.

In a further preferred embodiment of the method according to the invention under both aspect it is proposed that the structural members, provided they are disk-form, are subjected simultaneously to the CVD process in the horizontal position, on the one hand, and, on the other hand, vertically stacked one above the other. Therewith a batch of disk-form, horizontally positioned, stacked one above the other, structural members results.

Even though it is entirely possible to subject the structural members already as a batch to a treatment process preceding the CVD process, but, in particular, to transport them already as a batch to the CVD process, it is proposed highly preferably to stack the structural members through individual transport for the CVD process and to destack them preferably also through individual transport.

Therewith the advantage is attained that in the corresponding transport handling of the structural members, furthermore, an individual transport can be employed and yet the batch treatment in the layer deposition can be fully utilized.

This is highly advantageous in particular for the reason that wafers for the semiconductor structural element fabrication today already have dimensions of 200 mm×200 mm or a diameter of 200 mm, and thus a batch transport becomes highly complex and expensive.

With the method according to the invention in the embodiments so far and yet to be explained, as well as with the proposed CVD reactor according to the invention or the vacuum treatment installation proposed according to the invention with such, it becomes even possible to process with automation disk-form structural members, such as in particular wafers, having dimensions of more than 200 mm×200 mm or with corresponding diameters, even structural members with a size of minimally 300 mm×300 mm or with a diameter of minimally 300 mm. The larger the involved structural members, the more advantageous is the realization of the structural member transport in individual operation compared to batch transport. With this preferably proposed procedure, virtually no limits are set to increases of the wafer size.

In a further preferred embodiment of the method according to the invention the structural members are subjected to two or more treatment operations, among which the CVD process under conditions of ultrahigh vacuum is one, and the structural members are transported successively from one operation to the next under vacuum, along at least piece-wise linear and/or circular segment-form transport paths.

Therewith the CVD process under conditions of ultrahigh vacuum is integrated as a process station into a multi-process production method, into a cluster process proper. The structural members are therein customarily transported in a central transport chamber under vacuum freely programmable or in a predetermined sequence from one process station to the other and treated there. The operations carried out thereon can be, for example, apart from said UHV-CVD process, in/out-transportations, cleaning operations, further coating operations, etching operations, implantation operations, conditioning operations, for example in order to attain predetermined temperatures, and intermediate storage operation.

In a further highly preferred embodiment of the method according to the invention at least one of the UHV-CVD processes, applied according to the invention, is preceded or succeeded by plasma-enhanced reactive treatment processes of the structural members. Therein in a highly advantageous embodiment these plasma-enhanced reactive treatment processes are in each instance operated by means of a low-energy plasma discharge, with an ion energy E at the surface of the particular treated structural member of

0 eV<E≦15 eV.

These low-energy plasma-enhanced reactive processes, preferably employed in combination with the CVD processes employed according to the invention, can be plasma-enhanced CVD processes, but in particular plasma-enhanced reactive cleaning processes. This preferred combination has the noted advantage that the low-energy plasma processes preceding the UHV process, are optimally matched with respect to their surface effect to the surface conditions for the UHV-CVD process.

If, as is especially preferred, the UHV-CVD process is preceded by one or more low-energy plasma-enhanced cleaning process(es), in particular in a hydrogen and/or nitrogen process atmosphere, directly or with interconnected further processes, such as, for example, conditioning processes, their known passivating effect is utilized for the highly ensured purity maintenance of the particular surfaces up to the UHV-CVD process.

With respect to these addressed cleaning processes, reference is made to the application by the applicant:

WO 97/39472

WO 00/48779

as well as the U.S. application Ser. No.

09/792055.

As these cleaning methods even permit storing cleaned surfaces in ambient air before they are bonded, they permit in the present case optimum UHV-CVD coating, although the surfaces are only exposed to “low pressure” vacuum conditions before the UHV conditions.

In an especially preferred embodiment, such a low-energy plasma-enhanced reactive cleaning process immediately precedes the CVD process.

In a further preferred embodiment of the method according to the invention during the loading and/or unloading of the reaction volume with structural members to be treated there with CVD processes, a gas flow, preferably of a gas with hydrogen, is maintained in the reaction volume. It is thereby ensured that during the opening of this volume, which is necessary for the loading and/or unloading of the reactor volume, the latter is not contaminated.

For the CVD growing of layers within the scope of the production of semiconductor components or, as stated in the introduction, of components with quality requirements identical to semiconductor components, considerable significance is assigned to a homogeneous coating temperature distribution during the coating process. In known CVD methods under conditions of ultrahigh vacuum, this is attained thereby that outside of the UHV reactor, thus under normal clean-room atmosphere, segmented heating elements are provided distributed along the outer wall of the reactor. Through the number of heating elements and their individual heating power adjustment, the temperature uniformity in the reaction volume can be optimized.

For that reason, in a preferred embodiment of the method according to the invention, the average temperature and the temperature distribution in a reaction volume, in which a CVD process is being carried out, is measured and controlled, preferably measured and regulated.

But it is therein primarily of importance to master these parameters, namely average temperature and temperature distribution, on the structural members treated in the CVD process themselves. Therefore, in a further preferred embodiment it is proposed that the average temperature, and preferably also the temperature distribution, is measured and controlled, preferably measured and regulated, on the structural members themselves during the CVD process.

As stated, reactor volumes of prior known UHV-CVD reactors are heated by means of heating elements which are disposed along the outer wall. In a far preferred embodiment of the method according to the invention the temperature in a reaction volume in which the CVD process is being carried out, is set by means of heating elements disposed in vacuo within a vacuum recipient encompassing the reaction volume.

In a further preferred embodiment of the method according to the invention a reaction volume for the CVD process is initially evacuated to an ultra-high vacuum of minimally 10⁻⁸ mbar, subsequently, by admitting a process gas or a process gas mixture into the reaction volume, the total pressure therein is increased to the process pressure, wherein the reaction volume is encompassed by a vacuum with a total pressure in the proximity, preferably lower, of the process pressure.

This results in the reaction volume not needing to be vacuum-tight against the encompassing vacuum, and, if already present, a remaining gas diffusion from the latter into the encompassing vacuum does not take place which could affect the proportions in the reaction volume.

Reaction volume and the encompassing vacuum are preferably each pumped differently.

In a further preferred embodiment of the method according to the invention, the reaction volume and the vacuum encompassing it, are provided in a recipient disposed outside at ambient atmosphere, and the reaction volume for the loading and/or unloading of structural members communicates via the vacuum encompassing the reaction volume with a loading/unloading opening of the recipient.

In a further preferred embodiment of the method according to the invention, after structural members have been introduced into a reaction volume for the CVD process and after it has been closed, the structural members are supplied to their thermal equilibrium, while gas, preferably with hydrogen and/or with a process gas or process gas mixture, is being admitted into the reaction volume.

By admitting a gas and, corresponding to its thermal conductivity, attainment of the state of thermal equilibrium of the structural members can be accelerated.

Within the scope of the task, formulated in the introduction, forming the bases of the present invention under all of its aspect, it is also essential that structural members once they are introduced into the reaction volume of the CVD process, assume their thermal equilibrium as rapidly and undisturbed as feasible. Fulfilling this requirement critically contributes per se to an increase of the throughput of such a process. Therefore, under a third aspect of the present invention, a method for the production of components or of their intermediate products of the above type is proposed, in which several of the structural members are simultaneously subjected to a common CVD process under conditions of ultrahigh vacuum and in which the structural members are heated by means of heating elements, in which said heating elements are in thermal operational connection with the structural members through vacuum.

In a preferred embodiment the structural members, are retained during the CVD process on a support, and heating elements, preferably one each for individual structural members, are provided on the support.

Therewith the thermal interaction between heating elements and structural members takes place optimally directly, and these heating elements can be utilized as setting members for the average temperature or the temperature distribution on the structural members within the scope of a temperature average value and, preferably, also temperature distribution regulation, one each for the structural members. In particular for the regulated setting of the average temperature at the particular structural members and/or of the temperature distribution along these structural members it is highly advantageous, to acquire the particular instantaneous values, instantaneous temperature or instantaneous temperature distribution as directly as feasible at the particular structural members. This is in particular advantageous if the temperature setters, i.e. heating elements, are thermally closely coupled with the particular structural members, in each instance several heating elements if the temperature distribution is also to be regulated. Therefore, in a further preferred embodiment of the method according to the invention, under the third aspect of the present invention it is proposed that the structural members during the CVD process are retained on a support and thermal sensors are provided on the support, preferably one each assigned to the structural members.

In a highly preferred embodiment of the method according to the invention the solutions according to the invention under the first, second and third aspect are employed in combination.

For the solution of the above formulated task furthermore under the first aspect a vacuum treatment installation is proposed with an ultrahigh vacuum CVD reactor, wherein a support for several structural members to be treated simultaneously in the reactor is available, wherein the reactor has at least one loading/unloading opening, and in which said opening communicates with a vacuum transport volume for the structural members.

Under the above said second aspect, further, an ultrahigh vacuum CVD reactor is proposed with a support for several disk-form structural members to be treated simultaneously in the reactor, in which the support is developed for the reception of disk-form structural members in a horizontal position and stacked vertically.

Further preferred embodiments of the vacuum treatment installation according to the invention as well as of the ultrahigh vacuum CVD reactor according to the invention are apparent to a person skilled in the art on the basis of the following description of examples and are in particular specified in claims 23 to 45.

With respect to the production methods according to the invention especially preferred embodiments relate to the application of the CVD process for the deposition of single-atom layers or layer systems, so-called atomic layer deposition, and/or for the coating of surfaces with deep profiling, for example trench- or hole-form structures with a width/depth ratio of 1:5 or less (1:10, 1:20, . . . ), so-called deep trenches, and/or for the deposition of epitactic or hetero-epitactic layers.

In the following the invention will be explained by example in conjunction with Figures. Therein depict:

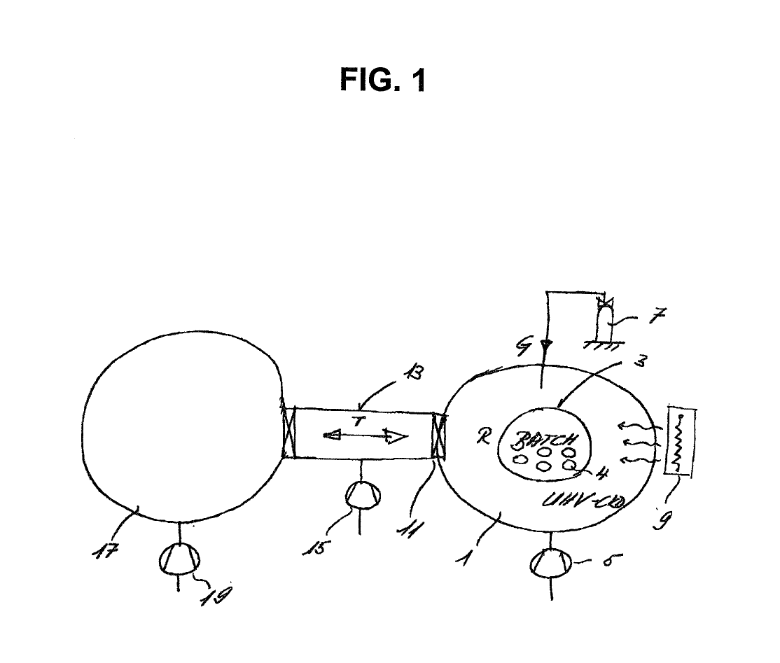

FIG. 1 schematic and simplified, the principle of a vacuum treatment installation according to the invention, operating according to a method according to the invention, under the first aspect of the invention,

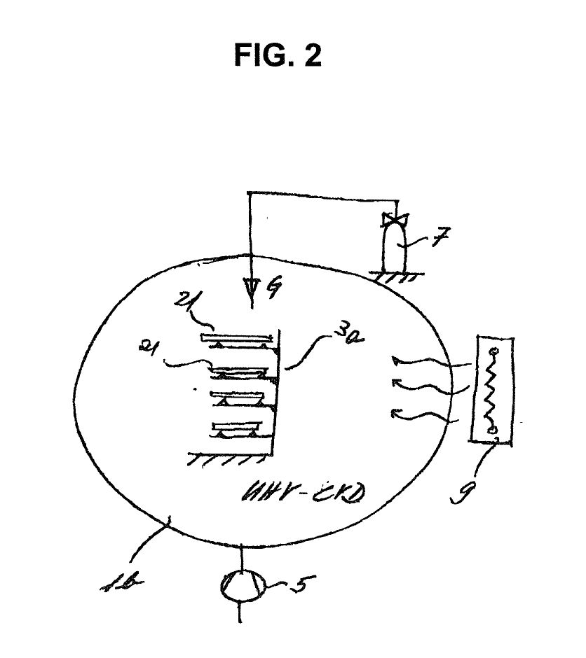

FIG. 2 in a representation analogous to that of FIG. 1, a UHV-CVD reactor according to the invention operating according to a method according to the invention, under the second aspect of the present invention,

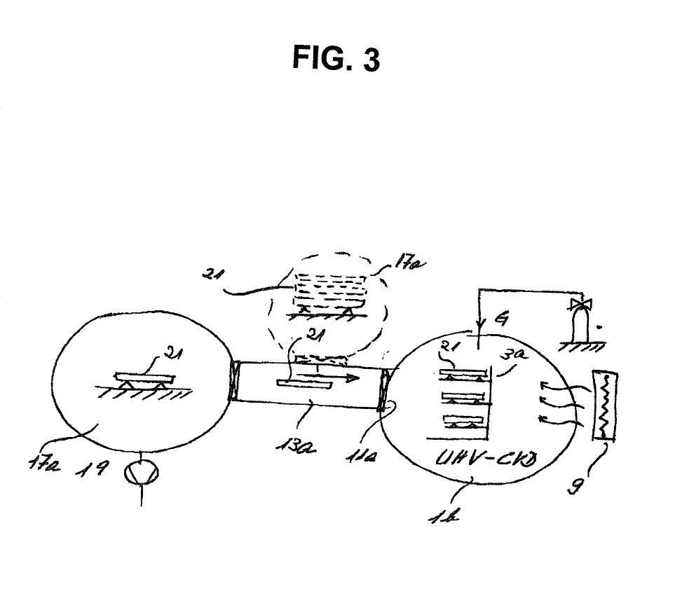

FIG. 3 In a representation analogous to that of FIGS. 1 or 2, a preferred embodiment of a vacuum treatment installation, operating according to a method according to the invention, with a UHV-CVD reactor according to the invention according to FIG. 2,

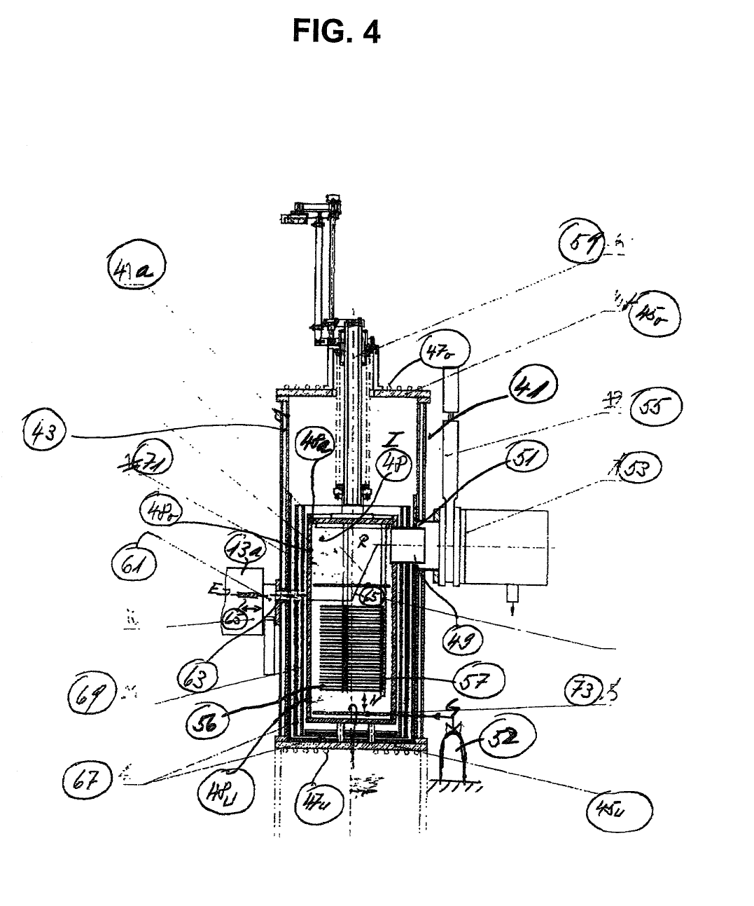

FIG. 4 in longitudinal sectional representation, a preferred embodiment of a UHV-CVD reactor according to the invention for application for carrying out a method according to the invention,

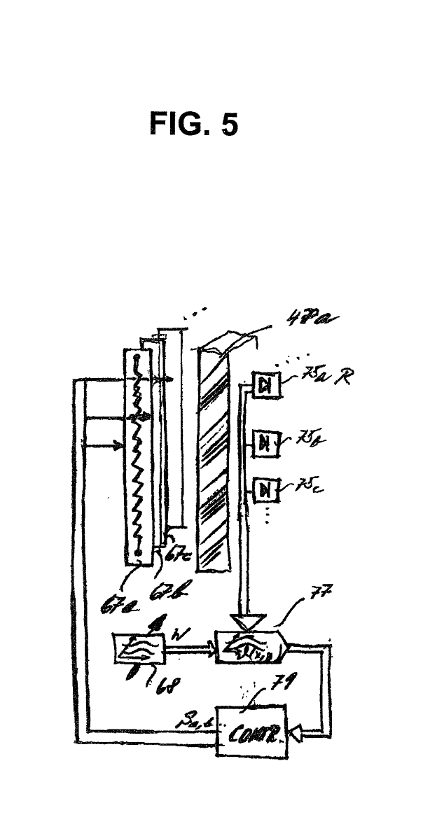

FIG. 5 schematically and simplified a partial section from a UHV-CVD reactor according to the invention, as depicted in FIG. 4, with disposition of heating elements and a regulation circuit for temperature parameters within the reaction volume of the reactor,

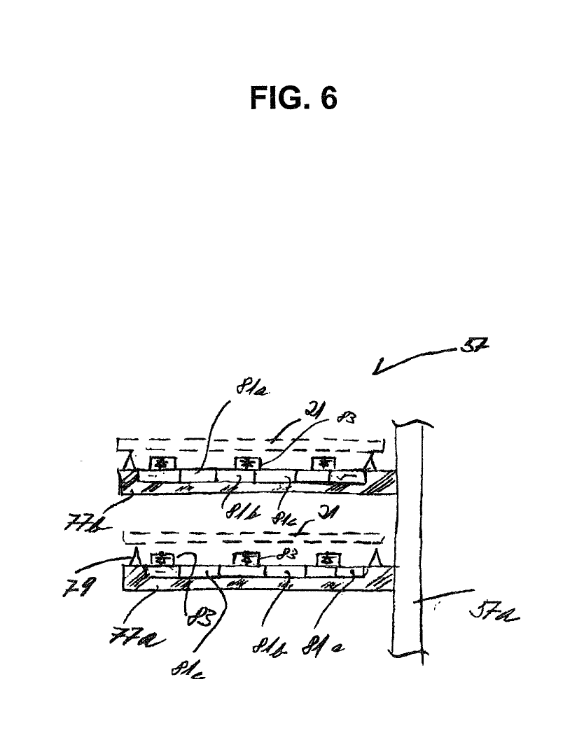

FIG. 6 schematically and simplified, a section of a component support employed in a UHV-CVD reactor according to the invention with temperature acquisition and temperature setting directly at the structural members themselves, and

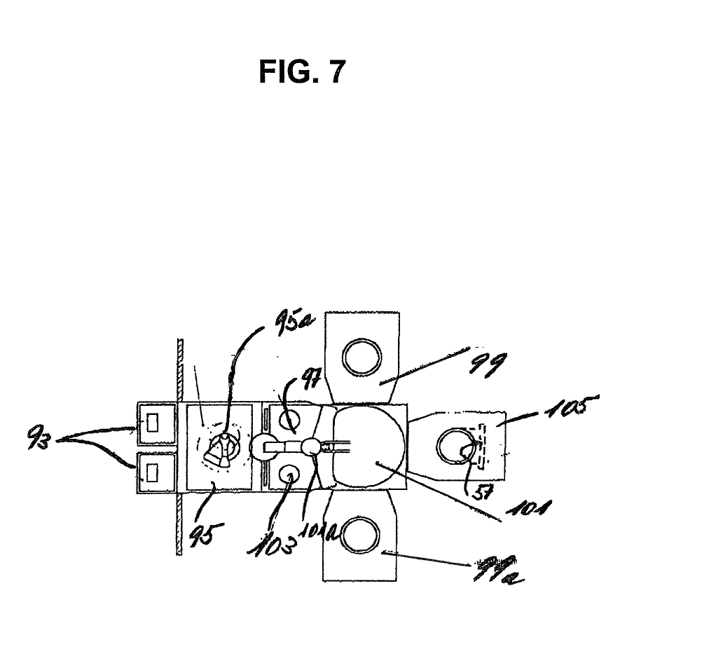

FIG. 7 schematically and in top view, a vacuum treatment installation according to the invention operating according to a method according to the invention, developed as a cluster installation and preferably equipped with at least one UHV-CVD reactor according to the invention.

In FIG. 1 is schematically depicted a vacuum treatment installation according to the invention, in particular for carrying out the production method according to the present invention and according to its first aspect. A UHV-CVD reactor 1 comprises a support 3 for a batch of several structural members to be treated. By means of a vacuum pump configuration 5 the reaction volume R in a reactor 1 is pumped down to a pressure of maximally 10⁻⁸ mbar. As is necessary for a CVD process, into reactor 1 a process gas or process gas mixture G is introduced from a gas tank configuration 7, and, for activating the process gas or process gas mixture G, in particular the structural members 4 placed on the support 3 are heated to the required reaction temperatures by means of a heating configuration 9 shown schematically.

The UHV-CVD reactor 1 has a loading/unloading opening 11 customarily closable or openable by means of a valve. According to the invention under the first aspect of the present invention the opening 11 connects the reaction volume R of the UHV-CVD reactor 1 with a vacuum transport chamber 13, which during operation is maintained under a vacuum as is schematically shown with the vacuum pump configuration 15. Therein a transport configuration, schematically indicated by the double arrow T, transports structural members, in particular to or from reactor 1. Furthermore, at least one further treatment chamber 17 is coupled to the transport chamber 13, and this chamber can be: a lock chamber, a further vacuum transport chamber, a coating chamber, a cleaning chamber, an etching chamber, a heating chamber, an intermediate storage chamber and an implantation chamber.

Under the first aspect of the present invention it is essential that the batch support 3 of the UHV-CVD reactor 1 is loaded and/or unloaded via a vacuum transport chamber 13, and that, under the first aspect of the production method according to the invention, structural members are already directly under vacuum before they are supplied to the CVD process under conditions of ultrahigh vacuum in reactor 1.

In a highly preferred manner the further chamber 17, which immediately precedes the reactor 1 with respect to transport T, is a vacuum chamber, as indicated with pump configuration 19 in FIG. 1, in particular a cleaning chamber employed virtually “in situ”. Structural members are transported T from chamber 17 into the reactor without vacuum interruption. They are there all treated simultaneously as a batch on support 3.

In FIG. 2 in a representation analogous to that of FIG. 1, thus highly simplified and schematically, is represented the production method according to the invention and a corresponding UHV-CVD reactor under the second aspect of the invention.

In an ultrahigh vacuum CVD reactor 1b according to the invention, as shown schematically with the vacuum pump configuration 5, pumped down to ultrahigh vacuum conditions corresponding to a residual gas partial pressure P_{R} of preferably maximally 10⁻⁸ mbar, structural members 21 are simultaneously CVD-treated as a batch retained on a batch support 3a. The structural members 21 have the form of a disk. As has already been explained in conjunction with FIG. 1, process gas or process gas mixture G is supplied from a gas tank configuration 7 to the reactor 1b and the structural members 21 are heated to the desired process temperature by means of a heating configuration 9.

According to the invention the disk-form structural members 21 are retained on the batch support 3a during the UHV-CVD process as a batch, as shown in FIG. 2, positioned horizontally and stacked vertically one underneath the other.

In FIG. 3, again in a representation analogous to that of FIGS. 1 or 2, a preferred embodiment of a vacuum treatment installation according to the invention or of a production method according to the invention, the first and second aspects of the invention are realized in combination. The UHV-CVD reactor 1b is developed as depicted and explained in conjunction with FIG. 2. Via a vacuum transport chamber 13a it is charged with individual, sequentially accumulating, disk-form structural members 21, which are stacked on batch support 3a in the manner explained. Thereby a cumbersome and complex handling of the entire structural member batch in the transport chamber 13a is avoided.

In the one or the several treatment chambers 17a—as stated shown in dashed lines—the structural members 21, preferably also positioned horizontally are treated and subsequently via transport chamber 13a individually supplied to the UHV-CVD reactors, whereby they are treated simultaneously while horizontally oriented and stacked vertically one above the other on support 3a. It is entirely possible to stack several structural members as a batch in individual or all treatment chambers 17a, but to supply them individually to the reactor 1b and/or a chamber 17a.

In FIG. 4 is shown in partial longitudinal section a preferred embodiment of a UHV-CVD reactor according to the invention, such as is preferably applied for carrying out the production method according to the invention or as a part of a vacuum treatment installation according to the invention.

The inventive UHV-CVD reactor per se comprises a reactor recipient 41, preferably of stainless steel. This is cooled intensively, for which purpose its wall 41a is at least sectionally thermally closely coupled with cooling members. Preferably and as shown in FIG. 4, the wall 41a is implemented at least in sections with a double wall having a cooling interspace 43.

Integrated therein is a cooling medium conducting system (not shown).

Although wall 41a according to FIG. 4 is shown as having been developed integrally and having the form of a cylinder, it can be realized as being comprised of several parts and optionally also in a form different from that of a cylinder. The reactor interior volume I is closed vacuum-tight at the top and bottom with flanges 45ₒ and 45ᵤ, which are also intensively cooled. In FIG. 4 is shown a cooling medium conducting system at 47ₒ or 47ᵤ for cooling the flanges 45ₒᵤ.

Within the reactor interior volume I a reaction recipient 48 encompasses the reaction volume R proper for the UHV-CVD method. At least the inner face of wall 48a of the reaction recipient 48 is fabricated of a material which is inert with respect to the process gases used during the UHV-CVD process in the reaction volume R.

The reaction volume R within reaction recipient 48 is pumped down to ultrahigh vacuum conditions via a pumping port 49. The remaining reactor interior volume I is pumped down, on the one hand, via a pumping port 51 to a pressure corresponding substantially to the process pressure within the reaction volume R. While with the pumping port 49 the reaction volume R is thus pumped to a residual gas partial pressure of preferably maximally 10⁻⁸ mbar or—during the process—to the process pressure of 10⁻¹ to 10⁻⁵ mbar, the remaining interior volume I is pumped to a residual gas partial pressure which corresponds substantially also to the total pressure in the reaction volume R during the UHV-CVD process, i.e. after the process gases have been introduced, thus to a pressure of 10⁻¹ mbar to 10⁻⁵ mbar depending on the process pressure.

According to FIG. 4 both pumping ports 51 and 49 are served by the same pump configuration 53. The particular pumping effect is determined by the corresponding dimensioning of the pumping cross section of pumping ports 49 or 51, which inter alia is also realized with the aid of a valve 55, preferably of a butterfly valve. It is understood that it is also possible to pump down the reaction volume R and the remaining volume of the interior reactor volume I by means of separate pump configurations.

Since during operation, i.e. during the UHV-CVD process, substantially identical total pressures obtain in the reaction volume R and in the remaining portion of the reactor interior volume I, the reaction volume R does not need to be closed absolutely vacuum-tight against the remaining portion of the reactor interior volume I. This separation, however, is so tight, that during process operation, a gas diffusion from the reaction volume R into the remaining portion of the reactor interior volume I occurs only to a minimal degree. The total pressure in the remaining portion of the reactor interior volume I can preferably therein be selected to be somewhat lower than the total pressure in the reaction volume R during the CVD process. Within the reaction volume R is mounted a component support 57, which in the preferred embodiment depicted in FIG. 4, receives disk-form structural members developed for example as wafers, positioned horizontally and stacked vertically. As indicated with the double arrow W, the support 57 is vertically driven so as to be up/down-movable under control. This takes place fundamentally and in view of FIG. 3 in order to be able to receive individual disk-form structural members 21 according to FIG. 3 into the batch or to deliver such through a loading/unloading opening analogous to opening 11a of FIG. 3. According to the preferred embodiment of FIG. 4, a loading/unloading opening through the wall 48a of the reaction recipient 48 as well as also through that of the reactor recipient 41 makes possible the reciprocal access from the reactor exterior to the reaction volume R. In the preferred embodiment according to FIG. 4 the reaction recipient 48 is divided into an upper portion 480 and lower portion 48ᵤ. The support 57 is anchored at the upper portion 48ₒ. With the aid of a lifting mechanism 59 the upper portion 48ₒ of the reaction recipient 48 is raised and therewith also support 57. In wall 41a is provided a loading/unloading opening 63 closable by means of a slot valve 61, and specifically with a plane of symmetry E, which is at least approximately aligned with the partition line 65 formed in the closed state of the recipient 48 between the upper 48ₒ and lower 48ᵤ portion of the reaction recipient 48.

Loading and unloading of this reactor takes place as follows:

The upper portion 48ₒ of reaction recipient 48 is raised, and thus also support 57, with the lifting mechanism 59. Through a stepping drive under control structural member receivers 56 on support 57 to be loaded or unloaded are positioned at the level of the loading/unloading opening 63. Therewith through this opening 63, as indicated with the disk-form structural member 65 in FIG. 4, through a transport mechanism flanged onto the opening 63, the support 57 or its receivers 56 can be sequentially loaded or unloaded.

If support 57 is fully loaded with structural members to be treated, in particular with wafers, the upper portion 48ₒ with support 57 is lowered and thus the reaction recipient 48 is closed.

It is understood, that, for example, for separate loading and unloading, two openings 63 can be provided.

During the loading/unloading process, the reaction volume R is maintained at the necessary process temperature. For this purpose, a heating configuration 67 is mounted in the remaining volume I, thus under vacuum, which encompasses the reaction recipient 48. The heating configuration 67 is preferably developed as a multizone radiant heater. Further, for improving the temperature uniformity between heating configuration 67 and reaction recipient 48 R, a heat diffusor 69, for example of graphite, is provided. Instead of providing a diffusor 69 as an individual structural part, the diffusor function can also be integrated with the wall 48a of the reaction recipient 48 thereby that the latter is coated on the inside and/or outside with a diffusor material, preferably with graphite. The wall of recipient 48 can optionally even act as a diffusor thereby that it is fabricated of a diffusor material, such as preferably graphite, is coated on the inside for example with Si or SiC, thus with a material, which, for directly limiting the reaction volume R, is inert against the heated process gases.

Preferably between the heating configuration 67 and the inner face of wall 41a, as is shown in FIG. 4, further a thermal insulator 71 is installed comprising, for example, a porous graphite material.

If the reaction recipient 48 is closed, the process proper for the layer deposition onto the structural members 56 retained on support 57 can be started. Via a gas inlet system 73 a process gas or process gas mixture G is supplied from a gas tank configuration 52 to the reaction volume R. With specifically set structural member temperature and preferably temperature distribution, the desired defined layer deposition takes place depending on the type of the process gas introduced and the time during which the structural members are exposed to the particular gas.

As already stated in the introduction, it is of great significance for the deposition of layers by means of UHV-CVD with a quality satisfactory even for semiconductor components, that the structural members during the CVD process have the same, and homogeneously distributed, process temperatures. The manner in which a heating configuration 67 is disposed in a vacuum was explained in conjunction with FIG. 4.

As shown schematically in FIG. 5, but not shown in FIG. 4 for reasons of clarity, along the wall 48a of the reaction recipient 48 are distributively disposed several heating radiators 67a, b, c, . . . Within reaction volume R are preferably mounted several thermal sensors 75a, 75b, etc. After they are digitized, the output signals of the thermal sensors are preferably supplied to a computing unit 77, in which, on the one hand and as indicated in the block of unit 77 the temperature distribution Θ(x,y) in reaction volume R is determined from the output signals of the thermal sensors 75a, b, c . . . and, additionally, the level of the average temperature Θ. To the computing unit 77 is further input by a presetting unit 68, shown schematically in FIG. 5, a nominal temperature distribution at a predetermined or predeterminable level Θ, which is compared in the computing unit 77 with the instantaneous distribution. Within the scope of a regulation, at the output side of the computing unit 77, into which preferably also the digitally operating regulator unit 79 is integrated, for each provided heating element 67a, b, . . . a setting signal Sa, b, c, . . . is output, such that through settings, differing in time and value, of these heating elements 67a, b . . . , acting as setting members, the temperature distribution Θ(x, y) in the reaction volume R and their temperature level Θ are regulated to the predetermined nominal distribution and the predetermined nominal level.

In addition to, or instead of, the thermal sensors 75a, b, c, preferably disposed in the reaction volume R preferably on the wall 48a of the reaction recipient 48, now preferably also directly on the site of interest, namely in the region of the structural members or wafer surfaces, in particular thermal sensors are provided, but preferably also heating elements.

According to FIG. 6, on the support 57, shown at an enlarged scale, schematically and in a section according to FIG. 4, are mounted several component or wafer receivers 77a, 77b. On these receivers 77a, b, . . . the disk-form structural members 21 to be treated are placed, for example, onto struts 79 projecting upward. On the surface of the receiver 77a, b, in this case facing the structural members 21, in each instance preferably several heating elements 81a, b are distributively provided, which consequently, specific to each structural member, are thermally closely coupled with its surface. Further, also distributed directly in the proximity of the emplaced structural members 21, thermal sensors 83 are installed. On the one hand, with the thermal sensors 83 on each structural member 21 the temperature distribution is separately determined, on the other hand, with the preferably provided several heating elements 81a, b, c . . . this temperature distribution and its absolute level can be affected, and/or via the multizone radiant heater of the heating configuration 67 of FIG. 4.

The measurement signal lines and setting signal lines from or to the thermal sensors 83 or heating elements 81 are guided (not shown) for example by the vertical arm 57a of support 57.

As an example will be described in the following a UHV-CVD process carried out in a reactor, such as has been described in conjunction with FIG. 4. Therein is specifically described the preferred growing of p-doped SiGe layers, for example for hetero bipolar transistors, wherein the flow of the process is readily possible for the deposition of other layers also.

The reaction volume R is heated to the necessary process temperature Tₚ for the deposition of said SiGe layers to 550° C.

The loading opening 63 is opened by opening the valve 61 opposite a vacuum transport chamber 13a by the in-flow of a flushing gas preferably of hydrogen, into reaction volume R, for example through gas inlet 73 from the gas supply of the tank configuration 52, which, for this purpose, also has a supply of flushing gas. Simultaneously, in the preferred embodiment according to FIG. 4, with the driving configuration 59 the upper portion 48ₒ with support 57 is raised.

While maintaining the flushing gas flow, the structural members, in particular wafers according to FIG. 4, are loaded into support 57, wherein the latter (together with portion 48ₒ) with the driving device 59 is lifted step by step in order to bring a free receiver 77 according to FIG. 6 into orientation with the loading opening 63 and the loading robot.

After filling the support 57, the loading opening 63 is closed with valve 61 and likewise the reaction volume R by lowering portion 48ₒ and simultaneously lowering support 57 into the treatment position shown in FIG. 4.

The structural members or wafers are now residing until the thermal equilibrium is attained, preferably with the simultaneous introduction of a gas increasing the thermal conductivity of the reaction volume atmosphere, for which purpose preferably again hydrogen gas is employed and/or silane for the production of said SiGe layers.

If the thermal conduction gas is not a process gas, its flow is stopped, and now via the inlet configuration 73 from the gas tank configuration 52 the process gas or process gas mixture G is allowed to flow into the closed reaction volume R. A first layer is deposited on the surface of the structural member or the wafer surface. During the production of components on the basis of structural members or wafers with a p-doped silicon germanium layer, here as the process gas silane is allowed to flow in.

Therewith a first coating is completed, and, if no further layers are to be deposited, the waters or structural members are removed from the reaction volume R. For this purpose

the flushing gas stream, preferably a hydrogen stream, is switched on again, and by opening valve 61 and raising portion 48ₒ the access for a transport robot provided in the vacuum transport chamber according to 13a is enabled.

Again, the support 57 is raised or lowered step by step, in order to align the treated wafers toward the loading/unloading opening 63 for access.

But if further layers are to be deposited, after the deposition of the first layer the procedure is as follows, described as an example of the deposition of said p-doped SiGe layers.

After the deposition of the Si layers, as was explained above, an undoped SiGe layer is deposited, thereby that to the silane stream germanium and helium are added, preferably at 5% of the silane stream.

Subsequently a boroethane-in-He stream is added and a doped SiGe layer is deposited. In this process step, additionally, carbon doping can be carried out parallel to the boron doping.

Again, deposition of an undoped SiGe layer takes place with the introduction of only silane and of germanium in helium, and, subsequently,

the deposition of an undoped Si layer while only silane is allowed to flow in.

The adjoining unloading of the support 57 takes place as explained.

The combined first and second aspects of the present invention, represented in conjunction with FIG. 3, now yield the highly advantageous option within the scope of the posed task, of combining UHV-CVD reactors via one or several vacuum transport chambers with further process modules without during the transport of the structural members, between the process modules and the one or the several provided UHV-CVD reactors, an interruption of the obtaining vacuum conditions occurring. Apart from said UHV-CVD reactors can be employed as process modules

further transport modules

lock modules

heating modules

further coating modules for PVD or CVD coating methods, or for PE-CVD (Plasma Enhanced CVD) methods

etching process modules, again with or without plasma enhancement

cleaning modules

storage modules

implantation modules.

Such multiprocess station installations can therein be developed linearly, in the sense that the structural member transport between the individual process stations takes place at least largely linearly. But preferably, at least to some extent, the provided process stations are disposed such that they are grouped circularly about a vacuum transport chamber to form a circular installation or a circular installation portion. Such installations at which several process stations are served through linear and/or circular transport paths under vacuum, are generally referred to as so-called “Cluster Tool Installations”.

In FIG. 7 is represented schematically and simplified a cluster tool installation according to the invention, building on the principle explained in conjunction with FIG. 3 and configured, for example, as a circular installation. In the depicted example the installation comprises a normal atmosphere-side cassette loading module 93, known as a so-called FOUP, Front Opening Unified Pod Module. This cassette loading module 93 is developed for receiving at least one wafer or structural member cassette 93a, in the case of treatment of wafers, for example, with a capacity of 25 vertically stacked, horizontally disposed wafers. Via a wafer handler 95 operating further in normal atmosphere, from the wafer cassette 93a individual wafers are transported into a first lock chamber 97. After pumping down this lock chamber 97, the further conveyance of the considered wafer into a cleaning module 99 takes place. This takes place through a vacuum transport chamber 101 and with the wafer handler 101a operating therein under vacuum. In the cleaning module 99 either a high-temperature cleaning under hydrogen takes place or a different gas phase cleaning or, and preferably, a cleaning yet to be described utilizing low-energy plasmas.

It is understood that, depending on the cleaning method selected, it can therein be of advantage to charge several cleaning modules sequentially and to carry out particular cleaning substeps at these modules. Further a storage chamber 103 is preferably provided as well as a second cleaning module 99ₐ. Therewith from the lock chamber 97 wafers can be cleaned in both cleaning modules 99 and 99ₐ in parallel, thus simultaneously, and they are subsequently placed by the handler 101a operating under vacuum into the storage cassette of the storage chamber 103. This is carried out until the number of wafers, which can be received by the support in a provided UHV-CVD reactor 105, after cleaning is available in storage chamber 103 for the UHV-CVD method. Both chambers 97 and 103 with cassette receivers are preferably developed as lock chambers.

Subsequently, i.e. after the required number of cleaned wafers has been placed into storage chamber 103, the conveyance takes place in a very short time of the individual wafers by means of the handler 101a operating in vacuum into support 57 of the UHV-CVD reactor 105 preferably developed as explained in conjunction with FIG. 4.

At the completion of the CVD process, the conveyance back of the wafers takes place from the support 57 of the UHV-CVD reactor 105 back into one of the two lock chambers 97 or 103, i.e. into their cassettes, and, subsequently, further from the corresponding lock chamber 97 or 103 into the cassette of the cassette loading module 93.

With the described fundamental procedure according to FIGS. 1 to 3 and also with the preferred UHV-CVD reactor according to FIG. 4 wafers can be transported, cleaned and lastly be UHV-CVD-treated in batch configuration, which are greater than 200×200 mm, or which have a diameter ø≧200 mm, which are even 300×300 mm or have a diameter ø>300 mm. In particular also for the reason that, apart from the batch configuration in the UHV-CVD process, the transport, and optionally also further treatment steps, takes place on individual wafers.

A typical handling sequence will subsequently be described in view of the circular cluster tool installation according to FIG. 7.

Wafers, for example 25 wafers, with a diameter ø of minimally 200 mm or dimensions of 200 mm×200 mm or even with a diameter ø of minimally 300 mm or dimensions of 300×300 mm are loaded into the atmosphere-side cassette module 93 according to FIG. 7.. By means of wafer handler 95 subsequently wafers are transported individually from cassette module 93 into the cassette of one of the lock chambers 97 or 103.

Individual wafers are loaded from the cassette 97 in the corresponding lock chamber 97 or 103 by means of the handler 101a operating in the vacuum transport chamber 101 into the cleaning module 99 and 99a and here cleaned with a typical cleaning time per wafer of 1 to 10 minutes.

Cleaned wafers from the cleaning modules 99 and 99a are loaded into the cassette of the lock chamber 103 or 93 not employed until this point, which now acts as an intermediate storage chamber. This takes place with the handler 101a operating in the vacuum chamber 101. A typical process time for cleaning 25 wafers and the transport up to this point is 65 minutes.

Now the cleaned 25 wafers in the cassette of the lock chamber 103 are loaded by means of handler 101 a into the UHV-CVD reactor 105. Loading of the cleaned 25 wafers from the intermediate store 103 into support 57 for the wafer batch in the UHV-CVD reactor 105 typically takes place within 5 minutes.

Now the coating process in the UHV-CVD reactor is started with a typical process time for p-doped SiGe layer systems of approximately 2 to 3 hours. During this time a new cassette with unprocessed wafers is introduced into the cassette loading module 93, and these wafers, in the manner described before, are cleaned on cleaning modules 99 and 99a, and intermediately stored in one of the lock chamber cassettes. After completion of the UHV-CVD process, the processed wafers are unloaded individually from support 57 by means of the wafer handler 101a and placed into the free lock chamber cassette 97 or 103. From there with the handler 95a operating under atmospheric pressure the conveyance back into a free cassette in cassette loading module 93 takes place.

Depending on the time proportions for the intended processes, it is entire possible to employ in combination two and more of the described UHV-CVD processes in a cluster installation and correspondingly also different configurations of further process modules.

In particular preferred is a combination of the described UHV-CVD processes or reactors with low-energy plasma-enhanced CVD coating methods and in particular with low-energy plasma-enhanced reactive cleaning methods. Therein are preferably employed DC plasmas, preferably low-voltage plasmas, generated for example by means of thermionic cathodes, which at the particular surfaces to be coated or to be cleaned develop ion energies E, for which applies:

0<E≦15 eV.

As a reactive gas for said low-energy plasma-enhanced cleaning methods are applied in particular preferred hydrogen and/or nitrogen or gas with a fraction of minimally one of said gases. Especially preferred and in view to the installation according to FIG. 7 the cleaning methods are realized immediately preceding the UHV-CVD processes or the corresponding process stations for low-energy plasma-enhanced reactive cleaning methods.

With the methods according to the invention, the vacuum treatment installation according to the invention or the UHV-CVD reactor according to the invention structural members are produced by

deposition of atom monolayers (atomic layer deposition) or by deposition of epitactic layers or by coating of deep-profiled surfaces, such as surfaces with so-called deep trenches.

1. Method for the production of components or of their intermediate products, in which the component, in the process of being produced, as a structural member is subjected to:
(a) a treatment process and next P1 (b) several of the structural members are simultaneously subjected to a common CVD process under conditions of ultrahigh vacuum,
characterized in that the treatment process is a vacuum process and from it the structural members are supplied to the CVD process under vacuum.

2. Method for the production of components or of their intermediate products according to characteristic (b) of the preamble of claim 1, wherein the structural members are disk-form, characterized in that they are subjected horizontally to the CVD process under conditions of ultrahigh vacuum.

3. Method as claimed in claim 1, characterized in that the structural members are disk-form and are subjected horizontally to the treatment process as well as also to the CVD process and are also transported horizontally from the treatment process into the CVD process.

4. Method as claimed in one of claims 1 to 3, characterized in that the structural members between a cleaning process preceding the CVD process and the CVD process remain under vacuum.

5. Method as claimed in one of claims 1 to 4, characterized in that the structural members are disk-form and are subjected positioned horizontally and vertically stacked one above the other to the CVD process simultaneously.

6. Method as claimed in claim 5, characterized in that the structural members are stacked through individual transport for the CVD process and/or are again unstacked from the CVD process.

7. Method as claimed in one of claims 1 to 6, characterized in that the structural members are subjected to two or more treatment operations, wherein the CVD process is one of the operations, and that the structural members are transported under vacuum successively from one operation to the other along an at least piece-wise linear and/or circular segment-form transport paths.

8. Method as claimed in one of claims 1 to 7, characterized in that the structural members before and/or after the CVD process are subjected to a reactive, low-energy plasma-enhanced treatment process with an ion energy E at the surface of the particular structural member to be treated of
0 eV<E≦15 eV.

9. Method as claimed in claim 8, characterized in that the structural members, before the treatment in the CVD process, are subjected to a low-energy plasma-enhanced reactive cleaning, preferably in an atmosphere comprising hydrogen and/or nitrogen.

10. Method as claimed in one of claims 1 to 9, characterized in that during the loading and/or unloading of a reaction volume with structural members to be treated there with a CVD process under conditions of UHV, in the reaction volume a gas flow, preferably of a gas with hydrogen, is maintained.

11. Method as claimed in one of claims 1 to 10, characterized in that the average temperature and the temperature distribution in a reaction volume of the CVD process are measured and controlled, preferably are measured and regulated.

12. Method as claimed in one of claims 1 to 11, characterized in that the average temperature and preferably the temperature distribution is measured and controlled, preferably measured and regulated, at the structural members themselves during the CVD process.

13. Method as claimed in one of claims 1 to 12, characterized in that a reaction volume, in which the CVD process is being carried out, is heated by means of heating elements which are disposed in vacuo within a recipient encompassing the reaction volume.

14. Method as claimed in one of claims 1 to 13, characterized in that a reaction volume for the CVD process is first evacuated to ultrahigh vacuum, subsequently by allowing a process gas or process gas mixture to flow into the reaction volume the total pressure therein is increased up to the process pressure, wherein the reaction volume is encompassed by a vacuum with a total pressure in the range of, preferably lower than, the process pressure.

15. Method as claimed in one of claims 13 or 14, characterized in that the reaction volume and the vacuum encompassing it are each pumped differently.

16. Method as claimed in one of claims 13 to 15, characterized in that the reaction volume and the vacuum encompassing it are provided in a recipient disposed outside at ambient atmosphere, and that the reaction volume for loading and/or unloading with structural members communicates via the vacuum encompassing the reaction volume with a loading/unloading opening of the recipient.

17. Method as claimed in one of claims 1 to 16, characterized in that, after structural members are introduced into a reaction volume for the CVD process, these are supplied to their thermal equilibrium while allowing a gas to flow into the reaction volume, preferably with hydrogen and/or with a process gas or process gas mixture.

18. Method for the production of components or of their intermediate products, in which several components in the process of production are subjected simultaneously as structural members to a common CVD process under conditions of ultrahigh vacuum, and the structural members are heated by means of heating elements, characterized in that the heating elements are operated under vacuum.

19. Method as claimed in claim 18, characterized in that the structural members for the CVD process are retained on a support and the heating elements, preferably assigned one each to structural members, are provided on supports.

20. Method preferably as claimed in one of claims 18 or 19, characterized in that the structural members during the CVD process are retained on a support and that, preferably one each assigned to the structural members, thermal sensors are provided on the support.

21. Vacuum treatment installation with an ultrahigh vacuum CVD reactor, wherein a support for several structural members to be treated simultaneously in the reactor is provided, with the reactor comprising at least one loading/unloading opening, characterized in that the at least one loading/unloading opening communicates with a vacuum transport chamber for structural members.

22. Ultrahigh vacuum CVD reactor with a support for several disk-form structural members to be treated simultaneously in the reactor, characterized in that the support is developed for receiving the structural members in their horizontal position and stacked vertically.

23. Vacuum treatment installation as claimed in claim 21 for the treatment of disk-form structural members, characterized in that a support is developed in the reactor for receiving the structural members in their horizontal position and stacked vertically.

24. Vacuum treatment installation as claimed in one of claims 21 or 23, characterized in that the vacuum transport chamber comprises a transport configuration, which transports single structural members or several of the structural members individually, therein disk-form structural members preferably in the horizontal position.

25. Vacuum treatment installation as claimed in one of claims 21, 23 or 24, characterized in that the vacuum transport chamber communicates with one or several further vacuum process chambers from the following group: lock chambers, coating chambers, cleaning chambers, etching chambers, UHV-CVD treatment chambers, conditioning chambers such as heating chambers, intermediate storage chambers, and implantation chambers.

26. Vacuum treatment installation as claimed in claim 25, characterized in that in the vacuum transport chamber a transport configuration is provided which is rotationally movably driven about an axis of rotation.

27. Vacuum treatment installation as claimed in claim 25, characterized in that in the vacuum transport chamber a transport configuration is provided, which comprises at least one driven, linearly movable part.

28. Vacuum treatment installation or UHV-CVD reactor as claimed in one of claims 21 to 27, characterized in that a reaction recipient encompasses the reaction volume and a reactor recipient, at least sectionally spaced apart from the reaction recipient, encompasses the latter, wherein the reaction recipient as as also the reactor recipient have each a pump connection.

29. Vacuum treatment installation or UHV-CVD reactor as claimed in claim 28, characterized in that the pumping connection on the reaction recipient has a significantly greater pumping cross section than the pumping connection on the reactor recipient and that both pumping connection are carried to the same pump configuration.

30. Vacuum treatment installation or UHV-CVD reactor as claimed in one of claims 28 or 29, characterized in that the reactor recipient is operationally connected with a cooling configuration.

31. Vacuum treatment installation or UHV-CVD reactor as claimed in claim 30, characterized in that the wall of the reactor recipient is developed at least sectionally as a double wall and the cooling configuration is disposed in the interspace of the double wall.

32. Vacuum treatment installation or UHV-CVD reactor as claimed in one of claims 28 to 31, characterized in that the reactor recipient comprises at least one loading/unloading opening for components and the reaction recipient is divided into two recipient portions, motor driven to be movable with respect to one another, which can be motor-driven jointly toward the recipient or can be separated toward the opening of the recipient, wherein the partition line of the two portions in the joined state is aligned toward the loading/unloading opening.

33. Vacuum treatment installation or UHV-CVD reactor as claimed in claim 32, characterized in that the loading/unloading opening is directed horizontally and the partition line of the two portions when joined extends also horizontally over a substantial section of its lengths which faces the loading/unloading opening.

34. Vacuum treatment installation or UHV-CVD reactor as claimed in claim 33, characterized in that on one of the two portions of the reaction recipient a support for a multiplicity of disk-form structural members is fastened with a multiplicity of receivers, each for at least one disk-form structural member in horizontal orientation and stacked in the direction of the relative motion of the reaction recipient portions such that through the relative motion of the portions under control in each instance one of the receivers is aligned toward the loading/unloading opening.

35. Vacuum treatment installation or UHV-CVD reactor as claimed in one of claims 32 to 34, characterized in that the portions can be separated through a linear relative motion or can be joined again.

36. Vacuum treatment installation or UHV-CVD reactor as claimed in one of claims 32 to 35, characterized in that one of the two separable portions of the reaction recipient is mounted stationarily on the reactor recipient.

37. Vacuum treatment installation or UHV-CVD reactor as claimed in one of claims 28 to 36, characterized in that in the reaction recipient terminates a gas supply configuration from a gas tank configuration with a process gas, and that at least the inner face of the reaction recipient wall comprises a material, preferably of graphite, which is resistant to the process gas brought to a predetermined process temperature.

38. Vacuum treatment installation or UHV-CVD reactor as claimed in one of claims 28 to 37, characterized in that between reaction recipient and reactor recipient a heating configuration is disposed.

39. Vacuum treatment installation or UHV-CVD reactor as claimed in claim 38, characterized in that between the heating configuration and interior volume of the reaction recipient a heat diffusor configuration is provided.

40. Vacuum treatment installation or UHV-CVD reactor as claimed in one of claims 28 to 40, characterized in that in the reaction recipient a support for a multiplicity of structural members is provided and that on the support at least one, preferably several, thermal sensors are disposed.

41. Vacuum treatment installation or UHV-CVD reactor as claimed in claim 40, characterized in that the at least one thermal sensor is an instantaneous value acquisition unit of a temperature regulating circuit and that a heating configuration is provided as its setting member between reactor recipient and reaction recipient and/or within the reaction recipient, preferably at least in part also on the support.

42. UHV-CVD reactor with a support for several structural members, characterized in that on the support at least one thermal sensor is provided.

43. UHV-CVD reactor as claimed in claim 42, characterized in that on the support at least one heating element is provided.

44. UHV-CVD reactor as claimed in one of claims 43 or 44, characterized in that the at least one thermal sensor is the instantaneous value acquisition unit of a temperature regulating circuit for the support.

45. UHV-CVD reactor as claimed in one of claims 41 to 44, characterized in that the support has several receivers each for a structural member, and that the at least one thermoelement is disposed on one of the receivers such that it is thermally closely coupled with a component received thereon.

46. Method as claimed in one of claims 1 to 20, characterized in that in the CVD process an atomic layer deposition (ALD) is carried out.

47. Method as claimed in one of claims 1 to 20, characterized in that in the CVD process a deep trenches layer deposition is carried out.

48. Method as claimed in one of claims 1 to 20, characterized in that in the CVD process an epitactic layer deposition is carried out.
